(19) United States
(12) Patent Application Publication
(10) Pub. No.: US 2020/0292401 A1
(43) Pub. Date: Sep. 17, 2020

(54) Pressure Sensor on a Ceramic Substrate

(71) Applicant: TDK Electronics AG, Munich (DE)

(72) Inventors: Benjamin Bohl, Berlin (DE); Jan Ihle, Raaba-Grambach (AT); Bert Hundertmark, Stahnsdorf (DE); Bernd Polder, Berlin (DE); Christian Wohlgemuth, Berlin (DE)

(21) Appl. No.: 16/650,937

(22) PCT Filed: Sep. 27, 2018
(86) PCT No.: PCT/EP2018/076318

§ 371 Date: Mar. 26, 2020

(30) Foreign Application Priority Data
Sep. 28, 2017 (DE) 10 2017 122 605.2

(51) Int. Cl. G01L 9/00; G01L 19/00; B81B 3/00; G01L 9/02

(52) U.S. Cl. CPC G01L 9/0051; G01L 19/0038; B81B 2201/0264; G01L 9/025; B81B 3/0018

(57) ABSTRACT

A pressure sensor is disclosed. In an embodiment a pressure sensor includes a housing comprising a housing wall, a sensor element arranged inside the housing, a ceramic substrate acting as a carrier of the sensor element and of its electrical connection arranged inside the housing and a first heating element arranged inside the housing or the housing wall.

This patent application is a national phase filing under section 371 of PCT/EP2018/076318, filed Sep. 27, 2018, which claims the priority of German patent application 102017122605.2, filed Sep. 28, 2017, each of which is incorporated herein by reference in its entirety.

### TECHNICAL FIELD

The invention relates to a pressure sensor for use in freezing or highly viscous media.

### BACKGROUND

During the measurement of pressure by means of pressure sensors in media under relatively difficult or extreme conditions, it happens that condensate, freezing or highly viscous media vitiate the measurement signal of the pressure sensors used. Such media may inter alia be hot, viscous, thin cold, aqueous or oily phases, cold thick oils, frozen water or fuel, as can occur in particular in the case of use in motor vehicles. The consequences of a vitiated measurement may be: insufficient exhaust gas purification, engine damage or generally damage to other elements of a process to be monitored. Because of an increased requirement for keeping the exhaust gas of internal combustion engines clean, it is, for example, necessary to carry out precise pressure measurements in various media directly after a cold engine start.

### SUMMARY OF THE INVENTION

Embodiments provide a pressure sensor which avoids the problems mentioned above and, for example, can already carry out a correct pressure measurement in an engine-relevant medium at a time close to a cold engine start, and can increase the lifetime of the pressure sensor.

Embodiments provide a pressure sensor, with which it is possible to measure a relative or absolute pressure. It comprises a housing, which in turn comprises a housing wall. The housing wall may be sealed for a measurement of absolute pressure, or may contain openings for measurement of a relative pressure, for example, in order to use atmospheric conditions as a reference pressure. The following are arranged in the housing: a ceramic substrate and a sensor element arranged thereon.

The sensor element is a component in which a pressure-induced deflection of a membrane can be determined. It may be configured in various technical variants: for example, as a direct pressure determination by using the piezo effect or as indirect pressure determination by measuring the extension of the membrane, for example, with the aid of resistive elements.

For the orientation of the sensor element, in what follows the side of the sensor element on which the membrane is located is referred to as the upper side of the sensor element, and the opposite side is referred to as the lower side of the sensor element. On the lower side, there is a media access in the sensor element, which makes the membrane accessible from the lower side for the medium carrying the pressure. The sensor element may be configured as an MEMS component.

The sensor element is fitted with its lower side on the ceramic substrate, which acts as a carrier and comprises an electrical connection for the sensor element. This connection is used to conduct a measurement signal from the pressure sensor, where it is externally processed and where a pressure is assigned to the measurement signal.

For the measurement of a relative pressure, below the sensor element there is an aperture in the ceramic substrate, through which a medium to be measured is fed to the media passage of the sensor element. The upper side of the sensor element is exposed to a reference pressure, which is, for example, atmospheric pressure. This may, for such a relative pressure measurement, reach into the pressure sensor through openings in the housing wall. In an alternative embodiment, the absolute pressure may be measured. In this case, there is no aperture in the ceramic substrate and the lower side of the sensor element is sealed. In addition, a gel container may be fitted around the sensor element on the ceramic substrate. This is filled with gel, which covers the upper side of the sensor element and thus protects it against moisture. The pressure to be measured is transmitted through the gel onto the membrane of the sensor element. It is also possible to use a sensor with a gel container and a filling for relative pressure measurement.

A heating element is furthermore part of the pressure sensor. It may be fitted at various positions in the pressure sensor, with the purpose of reaching an operating temperature in the pressure sensor which allows exact measurement. By the heating of the pressure sensor, possible solid and liquid condensates are defrosted, and possibly evaporated, and driven or heated out from the pressure sensor together with any highly viscous media that may be present. With the heating element, it is also possible to prevent formation of ice crystals which may damage or destroy the sensor element.

The heating element is, for example, configured to heat the pressure sensor to a temperature significantly above the freezing point. For example, heating to a temperature of between 20° C. and 50° C., in particular up to 160° C., is provided.

The various possible positions for the heating element all lie inside the pressure sensor. Exemplary positions are mentioned below in an inexhaustive list:

The heating element may be arranged:
on or in the ceramic substrate (positions A and B), in which case the heating element is preferably fitted in the vicinity of the electrical connections. The ceramic substrate may also be configured as a laminated ceramic. The heating element may, for example, be pressed onto a layer inside or on a surface of the ceramic substrate;
in the housing, for example internally on the housing wall (position C), the heating element being in direct contact with components of the housing by adhesive bonding, clamping or soldering;
inside the housing wall (position D); or
on the gel container (position G), if there is one in the embodiment. The heating element may also be integrated into the gel container.

The various embodiments of the heating element may comprise: a conductive plastic, a resistor formed, for example, as a meander, or a transistor having a positive temperature coefficient. The advantage of a possible meandering shape of the resistor is that the resistor is longer and consequently has a higher value, which leads to a higher heating power. With the use of a resistor having a positive temperature coefficient, external regulation of a heating power of the heating element is no longer necessary.

In another embodiment, the heating element is integrated into the housing of the sensor and is configured in such a way that it can generate and emit microwaves, with which, according to choice, the entire pressure sensor, individual pails thereof or the media to be measured are heated. In this way, the heating takes place directly at the desired position and, for example, in the medium, and the heating power applied can be used more optimally. Such a heating system may also be arranged at a different location of the sensor.

Supplying the heating element with electricity may be carried out in various ways. In this case, for example, there is the possibility of an electrical supply taking place by way of the electrical feed of the pressure sensor, or also the variant of an additional electricity supply independent of the pressure sensor. Separation of the energy supply has the advantage that the electrical feed to the heating element does not interfere with the measurement signals.

Besides the heating element described, the pressure sensor may comprise a further heating element in one of the designs and positions explained. This may be fitted at one of the positions described, but also at a position different to the position of the first heating element. By the use of a plurality of heating elements, the pressure sensor can be heated more homogeneously and therefore more efficiently.

The pressure sensor described above is, for example, configured for use in a motor vehicle, particularly for use in the exhaust gas region of a motor vehicle, for example, in the region of a diesel particle sensor or of a urea sensor.

According to another aspect, a method for operating the pressure sensor described above is provided. According to the method, during start-up of the pressure sensor, the heating element is turned on in order to heat the pressure sensor until an established operating temperature is reached. At the established operating temperature, a first pressure measurement is carried out. The heating element is turned on for heating as little as possible during operation of the pressure sensor in order to reduce the energy consumption. For example, the heating element is turned off when the operating temperature is reached. Freezing of the pressure sensor is subsequently prevented by the heat of the engine. As an alternative, continuous operation of the heating element is also possible in order to prevent freezing during driving.

### BRIEF DESCRIPTION OF THE DRAWINGS

The invention and its component parts will be explained in more detail below with the aid of a selection of exemplary embodiments and the associated schematic figures.

FIG. 1 shows a sectional view of a pressure sensor having a sensor element arranged on a ceramic substrate for absolute pressure measurement together with various positions for arranging a heating element;

FIG. 2 shows the sectional view of an alternative embodiment of the pressure sensor on a ceramic substrate for relative pressure measurement, with the various positions of a heating element and its possible relative arrangement; and

FIG. 3 shows the schematic sectional view of a sensor element.

### DETAILED DESCRIPTION OF ILLUSTRATIVE EMBODIMENTS

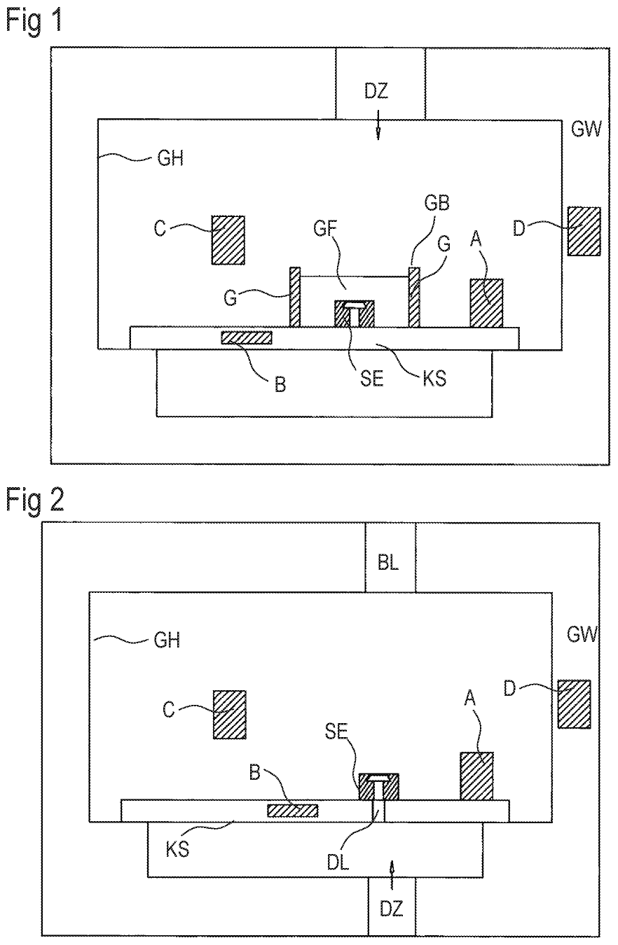

The sectional view shown in FIG. 1 shows the schematic structure of a pressure sensor DS for an absolute pressure measurement. It comprises a housing GH, comprising a housing wall GW. A ceramic substrate KS is fitted inside the housing, and a sensor element SE as well as a gel filling GF inside a gel container GB are arranged thereon. The sensor element is arranged on the ceramic substrate in such a way that pressure can act on the membrane of the sensor element only from one side. This side is the gel-covered upper side of the sensor element. The gel filling protects a pressure-sensitive membrane of the sensor element against moisture. Openings in the housing or the housing wall make it possible for atmospheric pressure also to be set up inside the housing and act on the gel, which transmits the pressure onto the membrane of the sensor element. Since the rear side of the sensor element is closed by the ceramic substrate, an absolute pressure measurement then takes place.

Furthermore, a plurality of different variants for the possible positioning of one or more heating elements H, in particular at positions A to G, are indicated. The exemplary fitting locations indicated for the heating element are as follows: the heating element may be arranged:
in or on the ceramic substrate (positions A and B);
in the housing, for example, internally on the housing wall (position C);
inside the housing wall (position D); or
on the gel container (position G).

The sectional view shown in FIG. 2 shows the schematic structure of a pressure sensor for a relative pressure measurement. It comprises a housing GH, comprising a housing wall GW. A ceramic substrate KS and a sensor element SE arranged thereon are fastened in the housing. The ceramic substrate KS comprises an aperture DL. The sensor element is arranged on the ceramic substrate in such a way that the aperture is located below sensor element. Through the aperture, a medium carrying pressure can be fed onto the lower side of the sensor element. The atmospheric pressure enters as a reference pressure through openings in the housing onto the upper side of the sensor element and thus makes a relative pressure measurement possible.

Furthermore, a plurality of different variants for the possible positioning of one or more heating elements H, in particular at positions A to D, are indicated. The exemplary fitting locations indicated for the heating element are as follows: the heating element may be arranged:
in or on the ceramic substrate (positions A and B);
in the housing, for example, internally on the housing wall (position C); or
inside the housing wall (position D).

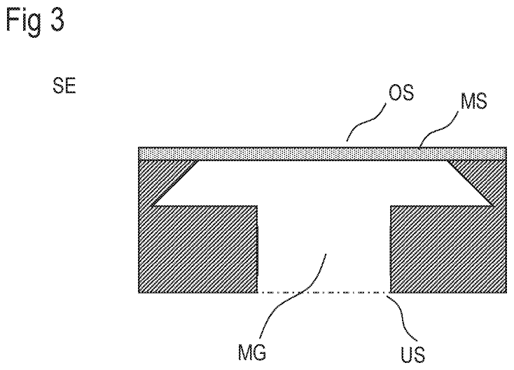

FIG. 3 shows an enlarged sectional view of the sensor element SE. In this case, a membrane of the sensor element MS can be seen, which in this case forms the upper side OS of the sensor element. Arranged opposite the upper side, there is a lower side US of the sensor element, on which a media passage MG to the membrane of the sensor element MS is located.

The form of the sensor element as represented in FIGS. 1, 2 and 3 is merely exemplary. Other forms or materials may be used in order to design a sensor element or the pressure sensor.

All representations in FIGS. 1, 2 and 3 are purely schematic and do not imply accurate size ratios of the components respectively represented.

1-18. (canceled)

19. A pressure sensor comprising:
a housing comprising a housing wall;
a sensor element arranged inside the housing;
a ceramic substrate acting as a carrier of the sensor element and of its electrical connection arranged inside the housing; and
a first heating element arranged inside the housing or the housing wall,
wherein the pressure sensor is configured to determine relative or absolute pressure.

20. The pressure sensor according to claim 19, wherein the first heating element is arranged on or in the ceramic substrate.

21. The pressure sensor according to claim 19, wherein the first heating element is arranged on an inner wall of the housing.

22. The pressure sensor according to claim 19, wherein the first heating element is arranged in the housing wall.

23. The pressure sensor according to claim 19, wherein the sensor element is arranged on the ceramic substrate in such a way that only an upper side of the sensor element is exposed to a pressure and only an absolute pressure is measurable.

24. The pressure sensor according to claim 19, wherein the ceramic substrate comprises an aperture, wherein the sensor element is arranged in the aperture such that independent media access is possible from an upper side and a lower side of the sensor element so that a relative pressure is measurable.

25. The pressure sensor according to claim 19,
wherein the sensor element comprises a membrane on an upper side,
wherein an upwardly open gel container is located on the ceramic substrate, and
wherein the gel container has a gel filling that covers the membrane, the gel filling acting as protection for the membrane.

26. The pressure sensor according to claim 25, wherein the first heating element is arranged on the gel container.

27. The pressure sensor according to claim 19, wherein the first heating element comprises an electrically conductive plastic.

28. The pressure sensor according to claim 19, wherein the first heating element comprises a resistive element having a positive temperature coefficient.

29. The pressure sensor according to claim 19, wherein the first heating element is integrated into parts of the housing wall and is configured to generate microwave radiation.

30. The pressure sensor according to claim 19, wherein the first heating element comprises an electricity supply separated from the pressure sensor.

31. The pressure sensor according to claim 19, wherein the sensor element is a MEMS component.

32. The pressure sensor according to claim 19, further comprising a second heating element arranged at a different location than the first heating element.

33. The pressure sensor according to claim 19, wherein the pressure sensor is configured to measure a pressure during a cold engine start in a motor vehicle, and wherein the first heating element is configured to heat the pressure sensor to an established operating temperature at which a first pressure measurement can be carried out.

34. The pressure sensor according to claim 19, wherein the first heating element is configured to heat the pressure sensor to a temperature between 20° C. and 160° C.

35. A method for operating the pressure sensor according to claim 19, the method comprising:
turning on the first heating element during a start-up of the pressure sensor in order to heat the pressure sensor until an operating temperature is reached.

36. The method according to claim ₃₅, further comprising turning off the first heating element when the operating temperature is reached.
